(19) United States
(12) Patent Application Publication
(10) Pub. No.: US 2007/0215881 A1
(43) Pub. Date: Sep. 20, 2007

(54) LIGHT-EMITTING ELEMENT AND MANUFACTURING METHOD THEREOF

(75) Inventors: Yoshiaki YAMAMOTO, Atsugi (JP); Yoshiharu HIRAKATA, Ebina (JP); Junichiro SAKATA, Atsugi (JP); Hiroki OHARA, Koza (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/680,354

(22) Filed: Feb. 28, 2007

(30) Foreign Application Priority Data
Mar. 3, 2006 (JP) 2006-058737

(51) Int. Cl. H01L 33/00

(52) U.S. Cl. 257/79

(57) ABSTRACT

It is an object of the present invention to provide a new light-emitting element and manufacturing method thereof in which actively diffusing a material into a film formation layer is utilized where an interface state and interdiffusion between a compound semiconductor substrate and a film formation layer formed thereover are not considered to be problematic. According to one feature of the present invention, unevenness is formed over the surface of a compound semiconductor substrate through chemical treatment, a compound semiconductor layer is formed over the surface of the compound semiconductor substrate having unevenness, atoms of the compound semiconductor substrate are diffused into the compound semiconductor layer through heat treatment, a first conductive layer is formed over the compound semiconductor substrate, and a second conductive layer is formed over the compound semiconductor layer.

### BACKGROUND OF THE INVENTION

1. Field of the Invention

The present invention relates to a light-emitting element and manufacturing method thereof. More specifically, the present invention relates to a light-emitting element in which a compound semiconductor layer functioning as a light-emitting layer is formed over a compound semiconductor substrate and a manufacturing method thereof.

2. Description of the Related Art

Recently, elements such as light-emitting diodes, photodiodes, photovoltaic cells, semiconductor lasers, high-speed transistors, and the like, in which, formed over a compound semiconductor substrate is a compound semiconductor of a different kind, have been used extensively. In addition, a good crystal can be obtained through use of a compound semiconductor substrate in an EL device which is driven by application of a high electric field, and a thin film inorganic EL device with high luminance can be obtained, as well.

However, when a compound semiconductor layer is formed over a compound semiconductor substrate, because an interface state is formed and interdiffusion is generated in the vicinity of a semiconductor interface by a thermal process due to differences in the lattice parameters and coefficients of thermal expansion, an injected carrier is trapped in the interface so that it is difficult to obtain good crystallinity. Consequently, obtaining good crystallinity in a simple layered structure is incredibly difficult to attain.

In order to solve these problems, research has been conducted in which, for example, a moderation (buffer) layer is used between a compound semiconductor substrate that contains an element belonging to group 13 of the periodic table and an element belonging to group 15 of the periodic table and a compound semiconductor layer that contains an element belonging to group 12 of the periodic table and an element belonging to group 16 of the periodic table formed over the compound semiconductor substrate, an anneal process is performed after film formation, and the like.

Furthermore, a manufacturing process has been examined in which reduction of interface states, low costs, and simplicity in production through formation of a porous semiconductor layer over a compound semiconductor substrate or use of a layer of an organic material as a buffer layer is considered. (For examples, see to Patent Document 1: Japanese Published Patent Application No. 2001-156321 and Patent Document 2: Japanese Published Patent Application No. 2003-86508.)

### SUMMARY OF THE INVENTION

However, it is an object of the present invention to provide a new light-emitting element which actively uses diffusion into a film formation layer and a manufacturing method thereof, in which influences by interface states and interdiffusion between a compound semiconductor substrate and a film formation layer formed thereover are not considered to be problematic. In addition, it is an object of the present invention to offer a light-emitting element in which, compared to traditional light-emitting elements, resistance has been lowered and luminance is high and a manufacturing method thereof.

A light-emitting element of the present invention is characterized by having a first conductive layer and a compound semiconductor layer formed over a compound semiconductor substrate and a second conductive layer formed over the compound semiconductor layer, where an element, the same element as that included in the compound semiconductor substrate, is contained in the compound semiconductor layer. In addition, as for the element contained in the compound semiconductor layer, after a compound semiconductor layer used to function as a light-emitting layer is formed over the compound semiconductor substrate, the element contained in the compound semiconductor substrate is diffused into the compound semiconductor layer by heat treatment or the like.

A light-emitting element of the present invention is characterized by having a first conductive layer and a compound semiconductor layer formed over a compound semiconductor substrate, a dielectric layer formed over the compound semiconductor layer, and a second conductive layer formed over the dielectric layer, where an element contained in the compound semiconductor layer is the same element as that contained in the compound semiconductor substrate.

In the above structure, the compound semiconductor layer is characterized by having a host material that is a compound that contains an element belonging to group 2 or group 12 of the periodic table and an element belonging to group 16 of the periodic table and an impurity element with a luminescent center.

In addition, the compound semiconductor layer can be formed as a plurality of stacked layers.

A manufacturing method of the present invention includes the following steps: forming a compound semiconductor layer over a compound semiconductor substrate; making an element contained in the compound semiconductor layer be diffused into the compound semiconductor substrate by heat treatment or the like; forming a first conductive layer over the compound semiconductor substrate; and forming a second conductive layer over the compound semiconductor layer.

A manufacturing method of the present invention includes the following steps: forming unevenness on the surface of the compound semiconductor substrate by chemical treatment; forming a compound semiconductor layer over the surface of the compound semiconductor substrate having unevenness; making an element contained in the compound semiconductor layer be diffused into the compound semiconductor substrate; forming a first conductive layer over the compound semiconductor substrate; and forming a second conductive layer over the compound semiconductor layer.

In addition, the manufacturing method of the present invention is characterized as one in which a dielectric layer is formed between the compound semiconductor layer and the second conductive layer of the above structure.

In addition, the manufacturing method of the present invention is characterized as one in which a layer that contains the impurity element with a luminescent center and the host material that is a compound containing an element belonging to group 2 or group 12 of the periodic table and an element belonging to group 16 of the periodic table is used as the compound semiconductor layer in the structure described above.

In addition, the manufacturing method of the present invention is characterized as one in which the compound semiconductor layer of the above structure can be formed as a plurality of stacked layers.

Through diffusion of the element of the compound semiconductor substrate into a film formation layer formed over the compound semiconductor substrate, a new energy level is formed in the film formation layer and the rate of movement of carriers to the film formation layer can be improved.

### BRIEF DESCRIPTION OF THE DRAWINGS

FIGS. 1A to 1D are diagrams used to illustrate an example of the light-emitting element of the present invention.

FIGS. 2A to 2C are diagrams used to illustrate an example of the light-emitting element of the present invention.

FIGS. 3A to 3D are diagrams used to illustrate an example of the light-emitting element of the present invention.

FIGS. 4A and 4B are diagrams used to illustrate an example of a light-emitting device that uses the light-emitting element of the present invention.

FIG. 5 is a diagram used to illustrate an example of an application configuration of a light-emitting device that uses the light-emitting element of the present invention.

FIGS. 6A and 6B are diagrams used to illustrate an example of a light-emitting device that uses the light-emitting element of the present invention.

FIGS. 7A to 7D are diagrams used to illustrate an example of an application configuration of a light-emitting device that uses the light-emitting element of the present invention.

### DETAILED DESCRIPTION OF THE INVENTION

Embodiment Modes of the present invention will be explained below with reference to the accompanying drawings. However, the present invention is not limited to the following explanation, and it is to be easily understood that various changes and modifications will be apparent to those skilled in the art. Therefore, unless such changes and modifications depart from the scope of the invention, they should be construed as being included therein. Note that identical portions or portions that have the same function in all figures used for explaining embodiment modes are denoted by the same reference numerals and detailed descriptions thereof are omitted.

### Embodiment Mode 1

In this embodiment mode, one example of a light-emitting element and manufacturing method thereof of the present invention will be described with reference to drawings.

The light-emitting element shown in this embodiment mode has a compound semiconductor layer 102 formed over a compound semiconductor substrate 101, a first conductive layer 103 that is electrically connected to the compound semiconductor substrate 101, and a second conductive layer 104 that is electrically connected to the compound semiconductor layer 102. Here, an example is shown in which the first conductive layer 103 is formed over the compound semiconductor substrate 101 and the second conductive layer 104 is formed over the compound semiconductor layer 102.

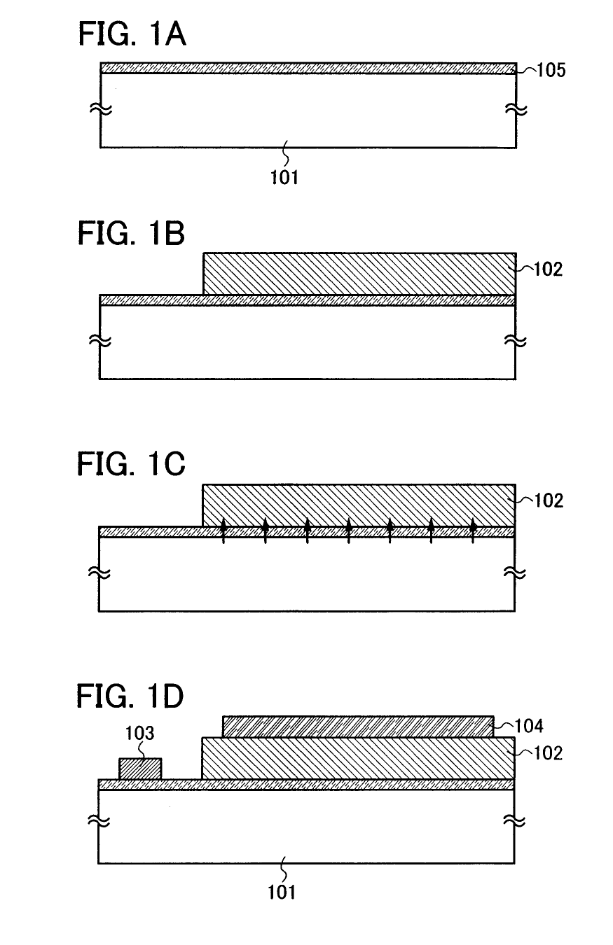

First, a compound semiconductor substrate 101 is prepared (FIG. 1A). GaAs, GaP, InP, or the like, for example, can be used for the compound semiconductor substrate 101. Furthermore, a p-type compound semiconductor may be used as a substrate. It is to be noted that a treated layer may be formed over the surface of the compound semiconductor substrate 101 in advance through performance of chemical treatment or the like.

When a p-type GaAs substrate is used for the compound semiconductor substrate 101, for example, a treated layer having an uneven surface can be formed over the surface through performance of chemical treatment with a mixture of sulfuric acid, a hydrogen peroxide solution, and water. The volume ratio of the mixture of sulfuric acid, the hydrogen peroxide solution, and water at this time is from 3:1:1 to 8:1:1, preferably from 3:1:1 to 4:1:1. Furthermore, the chemical treatment temperature is from 20° C. to 80° C.; preferably, the chemical treatment is performed under the condition of a temperature from 70° C. to 80° C.

In addition to the mixture described above being used for chemical treatment of the GaAs substrate, a mixture of ammonium hydroxide and a hydrogen peroxide solution, a mixture of orthophosphoric acid and a hydrogen peroxide solution, aqueous sodium hydroxide, a mixture of aqueous citric acid and ethanol, a mixture of bromine and ethanol, or the like may be used for performing chemical treatment of the GaAs substrate.

In addition, when GaP or InP is used for the compound semiconductor substrate 101, chemical treatment may be performed using a mixture of bromine and ethanol, hydrochloric acid, a mixture of hydrochloric acid and orthophosphoric acid, a mixture of hydrochloric acid and sulfuric acid, or the like.

Here, an example is shown in which a p-type GaAs substrate is used for the compound semiconductor substrate 101 and a treated layer 105 having an uneven surface is formed over the surface of the compound semiconductor substrate 101 through performance of chemical treatment of the GaAs substrate. Also, the treated layer 105 having the uneven surface may be formed by other than the above methods.

Next, a compound semiconductor layer 102 that is to become a light-emitting material is formed over the surface of the compound semiconductor substrate 101 by use of an electron beam evaporation technique (FIG. 1B). The deposition rate with the electron beam evaporation technique is from 0.1 nm/s to 20 nm/s; preferably, electron beam evaporation is performed at a deposition rate of from 0.5 nm/s to 2 nm/s. In addition, the compound semiconductor layer 102 is formed so as to have a thickness of from 100 nm to 2000 nm; preferably, the compound semiconductor layer 102 is formed so as to have a thickness of from 300 nm to 1000 nm. Substrate temperature during deposition is from 150° C. to 300° C.; preferably, the substrate temperature is set to be from 200° C. to 250° C.

Furthermore, in addition to being formed through use of the electron beam evaporation technique, the compound semiconductor layer 102 may be formed through use of a resistive heating method, a sputtering method, a CVD method, a molecular beam evaporation (MBE) method, or the like.

The compound semiconductor layer 102 can be formed of a host material that is a compound containing an element belonging to group 2 or group 12 of the periodic table and an element belonging to group 16 of the periodic table; a compound containing an element belonging to group 13 of the periodic table and an element belonging to group 15 of the periodic table; or a compound containing an element belonging to group 2 of the periodic table, an element belonging to group 13 of the periodic table, and an element belonging to group 16 of the periodic table; and an impurity element with a luminescent center.

For the host material, any of the following can be used. Zinc sulfide (ZnS), calcium sulfide (CaS), strontium sulfide (SrS), zinc oxide (ZnO), or the like can be used as the compound containing an element belonging to group 2 or group 12 of the periodic table and an element belonging to group 16 of the periodic table. Gallium nitride (GaN), aluminum nitride (AlN), or the like can be used as the compound containing an element belonging to group 13 of the periodic table and an element belonging to group 15 of the periodic table. Barium thioaluminate (BaAl₂S₄), calcium thiogallate (CaGa₂S₄), or the like can be used as the compound containing an element belonging to group 2 of the periodic table, an element belonging to group 13 of the periodic table, and an element belonging to group 16 of the periodic table.

For the impurity element, at least one of any of the following is included: manganese (Mn), europium (Eu), samarium (Sm), terbium (Tb), praseodymium (Pr), thulium (Tm), cerium (Ce), copper (Cu), silver (Ag), chlorine (Cl), and fluorine (F). It is to be noted that the molecular concentration of the impurity element with respect to the molecular concentration of the host material is from 0.1 mol % to 20 mol %; preferably, the molecular concentration is set to be from 0.5 mol % to 10 mol %.

In addition, the compound semiconductor layer 102 may be doped with an element belonging to group 11 of the periodic table (for example, copper (Cu), silver (Ag), or the like), an element belonging to group 13 or group 15 of the periodic table (for example, aluminum (Al), gallium (Ga), indium (In), nitrogen (N), phosphorus (P), arsenic (As), antimony (Sb), or the like), or an element belonging to group 14 of the periodic table (for example, carbon (C), silicon (Si), germanium (Ge), or the like), in advance, through a solid phase reaction or the like. Through doping of the compound semiconductor layer 102 with one or more of these elements, a change in the crystal system can be induced. It is to be noted that the molecular concentration of the dopant material is set to be from 0.1 mol % to 50 mol % with respect to the molecular concentration of the compound semiconductor layer 102; preferably, the molecular concentration of the dopant material is set to be from 0.5 mol % to 10 mol %.

After the compound semiconductor layer 102 is formed, heat treatment is performed (FIG. 1C). Here, annealing is performed using an oven, an electric furnace, or a quartz tube under an atmosphere containing nitrogen (N₂) and argon (Ar) at a temperature of from 550° C. to 800° C., preferably, from 600° C. to 700° C. The annealing is performed for a length of time of from 30 minutes to 12 hours, preferably, a length of time of from 1 hour to 4 hours. It is to be noted that, in addition to being performed through an annealing method, heat treatment may be performed through irradiation with a laser beam.

Through heat treatment, the element of the compound semiconductor substrate 101 is diffused from the compound semiconductor substrate 101 into a film formation layer (here, the compound semiconductor layer 102). As a result, a new energy level is formed in the compound semiconductor layer 102. Accordingly, the injection of carriers from the compound semiconductor substrate 101 into the compound semiconductor layer 102 is improved, and the probability for energy transfer to the new energy level formed in the compound semiconductor layer 102 is increased and luminous efficiency is improved. In addition, in this case, because adhesiveness improves through formation of the treated layer 105 over the compound semiconductor substrate 101, diffusion from the compound semiconductor substrate 101 into the compound semiconductor layer 102 occurs more noticeably, and more energy levels can be formed.

Generally, due to an auto-compensation effect, it is difficult to form a p-type compound semiconductor layer with low resistance from a compound semiconductor (for example, a compound semiconductor of ZnS, CaS, or SrS) containing an element belonging to group 2 or group 12 of the periodic table and an element belonging to group 16 of the periodic table. However, in the present invention, through active diffusion of the element of the compound semiconductor substrate (for example, a GaAs substrate) from a p-type compound semiconductor substrate into a compound semiconductor layer and formation of a new energy level, the resistance of a compound semiconductor layer containing an element belonging to group 2 or group 12 of the periodic table and an element belonging to group 16 of the periodic table can be lowered, and the rate of movement of carriers can be improved.

In addition, when a compound containing an element belonging to group 13 of the periodic table and an element belonging to group 15 of the periodic table (for example, GaAs, GaN, GaP, InP, or AlGaN) or a compound containing an element belonging to group 2 of the periodic table, an element belonging to group 13 of the periodic table, and an element belonging to group 16 of the periodic table (for example, BaAl₂S₄, CaGa₂S₄, or SrGa₂S₄) is formed over the compound semiconductor substrate 101, there are many defect levels due to a difference in lattice constants between the compound semiconductor substrate 101 and the compound semiconductor layer 102; however, with the treated layer 105 functioning as an intermediate layer between the compound semiconductor substrate 101 and the compound semiconductor layer 102, a compound semiconductor layer 102 in which defect levels have been reduced can be formed.

Next, a first conductive layer 103 that is electrically connected to the compound semiconductor substrate 101 and a second conductive layer 104 that is electrically connected to the compound semiconductor layer 102 are formed (FIG. 1D). Here, the first conductive layer 103 is formed over the compound semiconductor substrate 101, and the second conductive layer 104 is formed over the compound semiconductor layer 102.

The first conductive layer 103 can be formed of aluminum (Al), gold (Au), or the like at a thickness of from 100 nm to 500 nm by an electron beam evaporation technique, a resistive heating method, a sputtering method, a CVD method, an MBE method, or the like.

The second conductive layer 104 can be formed of a conductive material with a light-transmitting property by an electron beam evaporation technique, a resistive heating method, a sputtering method, a CVD method, an MBE method, or the like, so as to have a thickness of from 100 nm to 500 nm. The conductive material with a light-transmitting property may be formed of, for example, indium tin oxide (ITO), indium tin oxide containing silicon or silicon oxide, indium zinc oxide (IZO), indium tin oxide containing tungsten oxide and zinc oxide (IWZO), or the like.

A light-emitting element can be formed through performance of the above steps. The light-emitting element shown in FIG. 1 can be the type of light-emitting element that is driven by direct current. In this case, the first conductive layer 103 is used as an anode, and the second conductive layer 104 is used as a cathode.

### Embodiment Mode 2

In this embodiment mode, a light-emitting element whose structure differs from that of the above embodiment mode will be explained with reference to drawings.

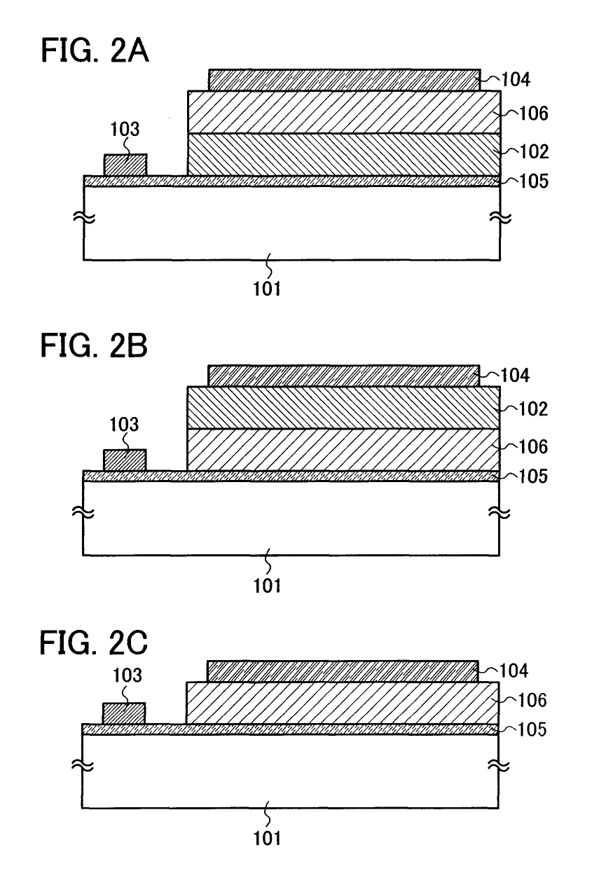

The light-emitting element shown in the present embodiment mode is one which has a first compound semiconductor layer 102 formed over a compound semiconductor substrate 101, a second compound semiconductor layer 106 formed over the first compound semiconductor layer 102, a first conductive layer 103 that is electrically connected to the compound semiconductor substrate 101, and a second conductive layer 104 that is electrically connected to the second compound semiconductor layer 106 (FIG. 2A). The structure shown in FIG. 1D has become a structure in which the second compound semiconductor layer 106 is formed between the compound semiconductor layer 102 and the second conductive layer 104. Furthermore, the compound semiconductor layer may be formed as a stacked layer of three or more layers.

A compound of an element belonging to group 1 of the periodic table, an element belonging to group 13 of the periodic table, and an element belonging to group 16 of the periodic table (for example, a compound such as CuAlS₂, CuGaS₂, CuInS₂, AgAlS₂, AgGaS₂, AgInS₂, or the like) or a chalcopyrite compound of an element belonging to group 12 of the periodic table, an element belonging to group 14 of the periodic table, and an element belonging to group 15 of the periodic table (for example, a compound such as ZnSiP₂, ZnGeP₂, or the like) can be used for the second compound semiconductor layer 106.

In addition, the second compound semiconductor layer 106 may be doped with an element belonging to group 11 of the periodic table (for example, copper (Cu), silver (Ag), or the like), an element belonging to group 13 or group 15 of the periodic table (for example, aluminum (Al), gallium (Ga), indium (In), nitrogen (N), phosphorous (P), arsenic (As), antimony (Sb), or the like), or an element belonging to group 14 of the periodic table (for example, carbon (C), silicon (Si), germanium (Ge), or the like), in advance, through a solid phase reaction. Through doping of the compound semiconductor layer 102 with one or more of these elements, a change in the crystal system can be induced. It is to be noted that the molecular concentration of the dopant material is set to be from 0.1 mol % to 50 mol % with respect to the molecular concentration of the compound semiconductor layer 106; preferably, the molecular concentration is set to be from 0.5 mol % to 10 mol %.

It is to be noted that the compound semiconductor substrate 101, the first compound semiconductor layer 102, the first conductive layer 103, and the second conductive layer 104 can be formed using the materials and manufacturing methods shown in the above embodiment mode.

In addition, in the structure shown in FIG. 2A, heat treatment is performed after the first compound semiconductor layer 102 and the second compound semiconductor layer 106 are formed and stacked over the compound semiconductor substrate 101. Consequently, the element of the compound semiconductor substrate 101 is diffused from the compound semiconductor substrate 101 into a film formation layer (here, either one of the first compound semiconductor layer 102 or second compound semiconductor layer 106 or both of them). As a result, a new energy level is formed in the first compound semiconductor layer 102 and the second compound semiconductor layer 106. Accordingly, the injection of carriers from the compound semiconductor substrate 101 into the film formation layer is improved, and the probability for energy transfer to the new energy level formed in the film formation layer is increased and luminous efficiency is improved.

Furthermore, in addition to the structure shown in FIG. 2A, it is possible to set the structure as one in which a second compound semiconductor layer 106 is formed over a compound semiconductor substrate 101 and a first compound semiconductor layer 102 is formed thereover (FIG. 2B). In this case, a second conductive layer 104 is formed over the first compound semiconductor layer 102.

In addition, it is possible to set the structure as one in which a first compound semiconductor layer 102 is not formed, but a second compound semiconductor layer 106 is formed over a compound semiconductor substrate 101 and a second conductive layer 104 is formed over the second compound semiconductor layer 106 (FIG. 2C).

A light-emitting element can be formed through performance of the above-mentioned steps. The light-emitting element shown in FIGS. 2A to 2C can be the type of light-emitting element that is driven by direct current. In this case, the first conductive layer 103 is used as an anode, and the second conductive layer 104 is used as a cathode.

The present embodiment mode can be freely combined with the above embodiment mode.

### Embodiment Mode 3

In this embodiment mode, a light-emitting element whose structure differs from that of the above embodiment modes will be explained with reference to drawings.

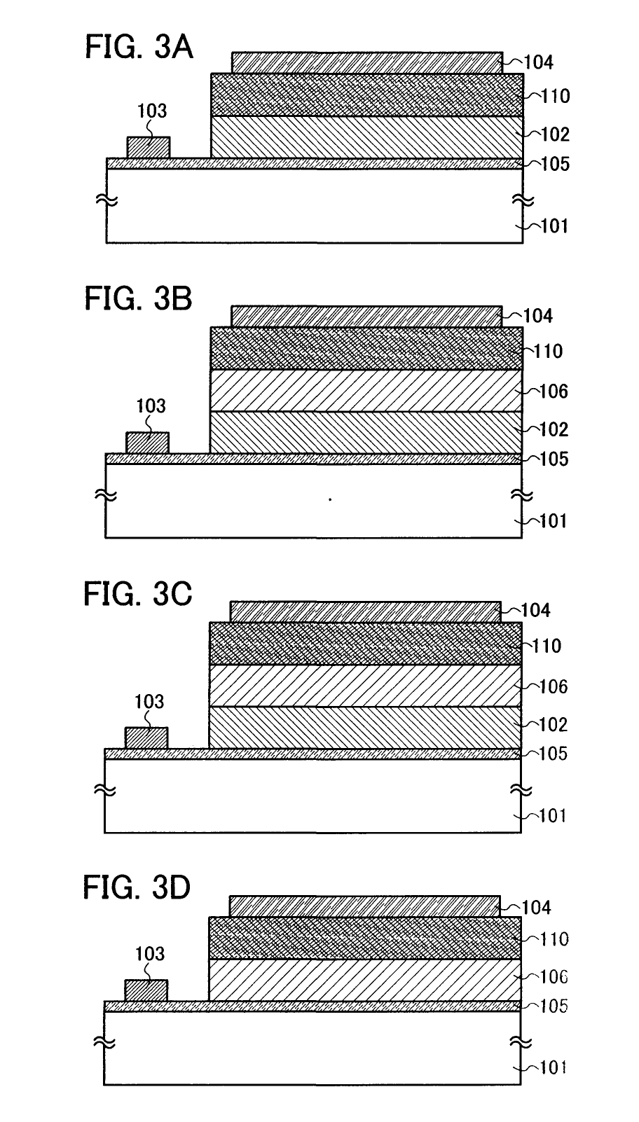

The light-emitting element shown in the present embodiment mode is one which has a compound semiconductor layer 102 formed over a compound semiconductor substrate 101, a dielectric layer 110 formed over the compound semiconductor layer 102, a first conductive layer 103 that is electrically connected to the compound semiconductor substrate 101, and a second conductive layer 104 that is electrically connected to the dielectric layer 110 (FIG. 3A). The structure shown in FIG. 1C has become a structure in which the dielectric layer 110 is formed between the compound semiconductor layer 102 and the second conductive layer 104.

The dielectric layer 110 is formed as a single-layer or multilayer structure of BaTiO₃, SrTiO₃, Ta₂O₅, Si₃N₄, SiO₂, Al₂O₃, Y₂O₃, or the like at a thickness of from 300 to 1000 nm by an electron beam evaporation method, a resistive heating method, a sputtering method, a CVD method, an MBE method, or the like.

With the dielectric layer 110 being formed between the compound semiconductor layer 102 and the second conductive layer 104, driving by alternating current becomes possible.

Furthermore, in addition to the structure shown in FIG. 2A, the structure may be set as one in which a dielectric layer 110 is formed between a second compound semiconductor layer 106 and a second conductive layer 104 (FIG. 3B); in addition to the structure shown in FIG. 2B, the structure may be set as one in which a dielectric layer 110 is formed between a first compound semiconductor layer 102 and a second conductive layer 104 (FIG. 3C); in addition to the structure shown in FIG. 2C, the structure may be set as one in which a dielectric layer 110 is formed between a second compound semiconductor layer 106 and a second conductive layer 104 (FIG. 3D).

The light-emitting element shown in FIG. 3 can be the type of light-emitting element that is driven by alternating current.

The present embodiment mode can be freely combined with the above embodiment modes.

### Embodiment Mode 4

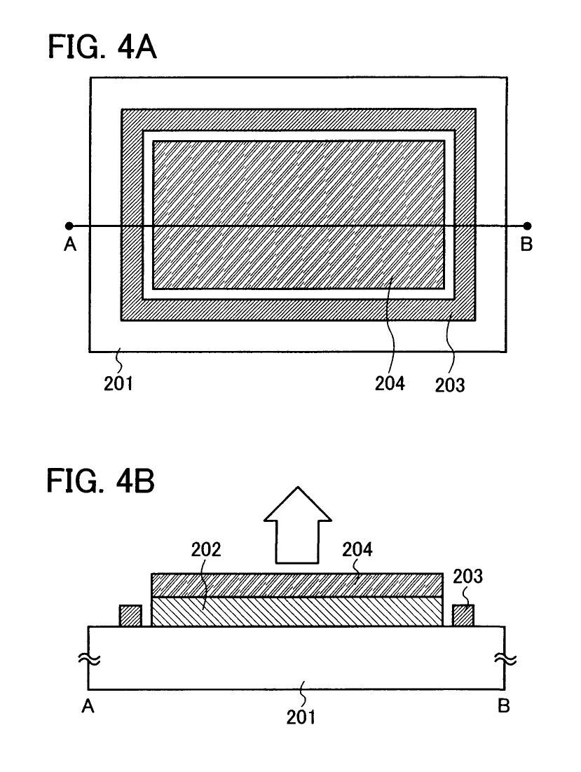

In the present embodiment mode, a light-emitting device that includes a light-emitting element of the present invention will be described with reference to FIGS. 4A and 4B. It is to be noted that FIG. 4A shows a top view and FIG. 4B shows a cross-sectional view of a cross-section taken along the line A-B in FIG. 4A.

In FIGS. 4A and 4B, a first conductive layer 203 and a compound semiconductor layer 202 are formed over a compound semiconductor substrate 201. In addition, a second conductive layer 204 is formed over the compound semiconductor layer 202. It is to be noted that, for the compound semiconductor substrate 201, the compound semiconductor layer 202, the first conductive layer 203, and the second conductive layer 204, those described in the above embodiment modes can be used.

The compound semiconductor layer 202 is surrounded by the first conductive layer 203. A light-emitting device that includes the light-emitting element shown in FIGS. 4A and 4B can be driven by direct current. It is to be noted that, as described in the above embodiment modes, forming a dielectric layer between the compound semiconductor layer 202 and the second conductive layer 204 and driving the light-emitting device that includes the light-emitting element shown in FIGS. 4A and 4B by alternating current may be done, as well. In addition, the compound semiconductor layer 202 may be formed as a stacked layer.

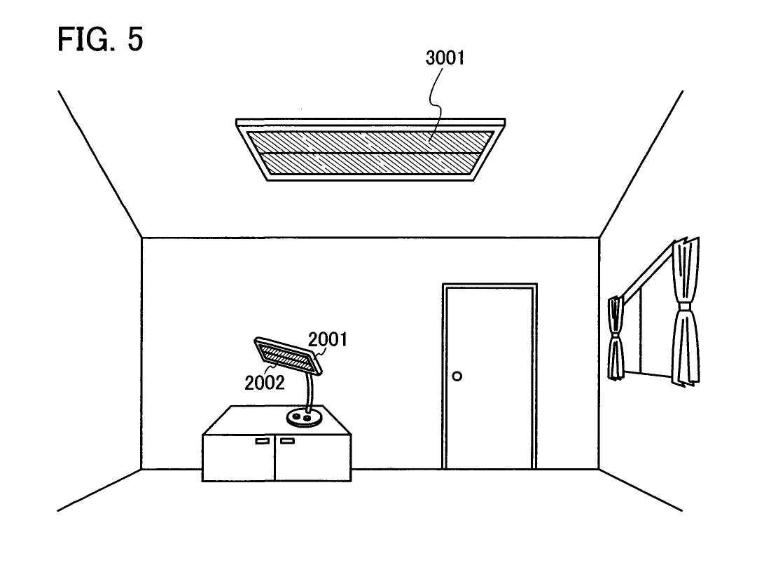

Next, an example of an application mode of the light-emitting device shown in the present embodiment mode is shown in FIG. 5.

In FIG. 5, an example is shown in which a light-emitting device employing the light-emitting element of the present embodiment mode is used as the lighting unit of a desk lamp. The desk lamp shown in FIG. 5 has a case 2001 and a light source 2002, where a light-emitting device of the present invention is used as the light source 2002. Because the light-emitting device of the present invention is one in which emission of light at high luminance is possible, when detailed work is being performed, the area at hand where the work is being performed can be brightly lighted up.

The present embodiment mode can be freely combined with the above embodiment modes.

### Embodiment Mode 5

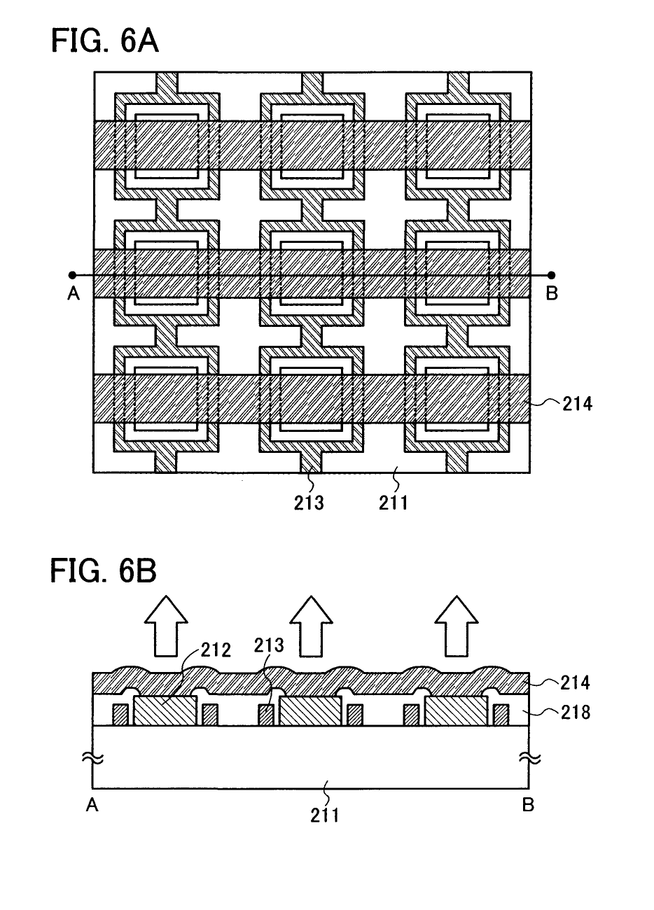

In the present embodiment mode, a light-emitting device differing from that of Embodiment Mode 4 will be described with reference to FIGS. 6A and 6B. It is to be noted that FIG. 6A shows a top view and FIG. 6B shows a cross-sectional view of a cross-section taken along the line A-B in FIG. 6A.

The light-emitting device shown in the present embodiment mode is a light-emitting device in which driving of a light-emitting element can be performed without formation of an element, such as a transistor or the like, used for driving.

In FIGS. 6A and 6B, a compound semiconductor layer 212 and a first conductive layer 213 are formed over a compound semiconductor substrate 211. In addition, an insulating film 218 is formed so as to cover an edge of the compound semiconductor layer 212 and the first conductive layer 213, and a second conductive layer 214 is formed as selected so as to cover the insulating layer 218. The second conductive layer 214 is formed so as to be in contact with an upper surface of the compound semiconductor layer 212. In addition, the first conductive layer 213 is formed so as to surround the compound semiconductor layer 212. It is to be noted that, for the compound semiconductor substrate 211, the compound semiconductor layer 212, the first conductive layer 213, and the second conductive layer 214, those described in the above embodiment modes can be used.

Here, a 3-pixel by 3-pixel light-emitting element is shown. The first conductive layer 213 is formed so that the pixels are electrically connected in a first direction (in a the pixels are electrically connected in a second direction (in a horizontal direction in the drawing).

A light-emitting device that includes the light-emitting element shown in FIGS. 6A and 6B can be driven by direct current. It is to be noted that, as described in the above embodiment modes, forming a dielectric layer between the compound semiconductor layer 212 and the second conductive layer 214 and driving the light-emitting device that includes the light-emitting element shown in FIGS. 6A and 6B by alternating current may be done, as well. In addition, the compound semiconductor layer 212 may be formed as a stacked layer.

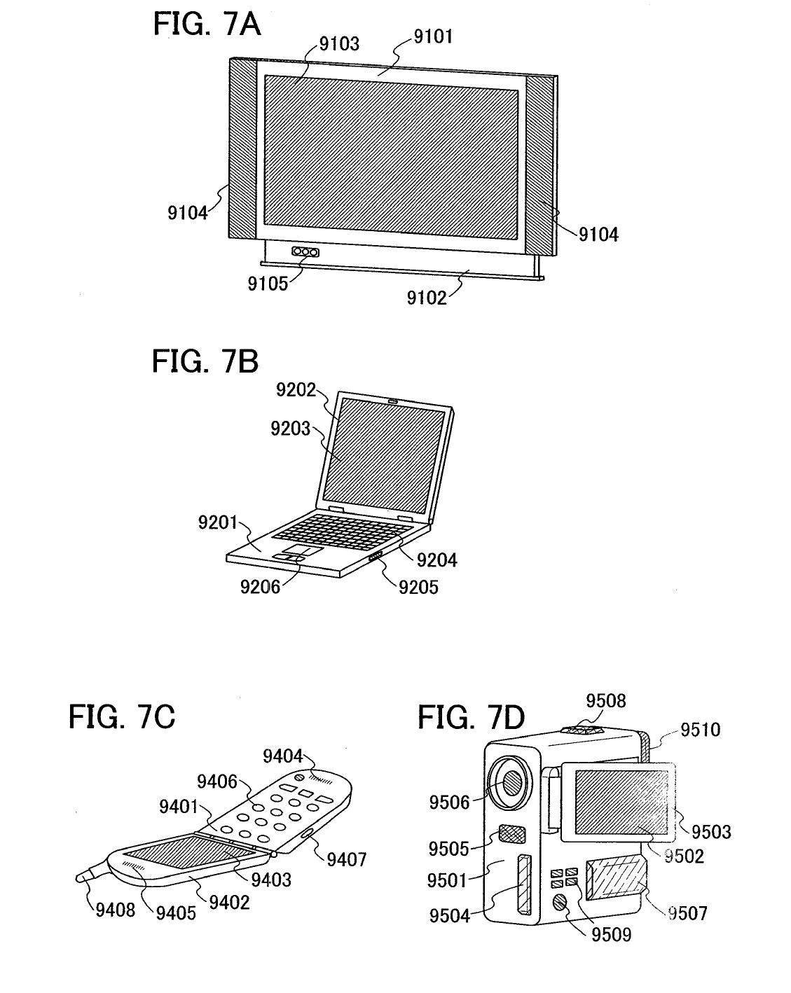

Next, examples of application modes of the light-emitting device shown in this embodiment mode are shown in FIGS. 7A to 7D.

For electronic devices manufactured using a light-emitting device of the present embodiment mode, a camera such as a video camera, a digital camera, or the like; a goggle-type display; a navigation system; an audio reproducing system (for example, a car audio system, an audio component system, or the like); a computer; a game machine; a handheld terminal (for example, a portable computer, a cellular telephone, a portable game machine, an electronic book reader, or the like); an image reproducing device (to be specific, a device that can play and includes a display device that can display images for recording media such as a Digital Versatile Disc (DVD) and the like); and the like can be given. Some specific examples thereof are shown in FIGS. 7A to 7D.

The television of FIG. 7A is a television device manufactured with a light-emitting device of the present embodiment mode and includes a case 9101, a support stand 9102, a display 9103, speakers 9104, video input terminals 9105, and the like. The display 9103 of this television device is one in which the same light-emitting elements as those described in the present embodiment mode are arranged in the form of a matrix. The light-emitting elements have the characteristics of high luminous efficiency and low drive voltage. In addition, short-circuiting due to impacts or the like caused by an external source can be prevented. Because the display 9103 made up of the light-emitting elements has the same characteristics, deterioration in the picture of this television device is reduced and low power consumption can be achieved. Through such characteristics, because deterioration compensating functions and power supply circuits can be greatly reduced in number or size, a reduction in the size and weight of the case 9101 and the support stand 9102 can be achieved. Because low power consumption, high picture quality, and a reduction in the size and weight of the television device produced using the light-emitting device of the present embodiment mode can be achieved, a device adapted for use in a household environment can be provided thereby.

The computer of FIG. 7B is a computer manufactured with a light-emitting device of the present embodiment mode and includes a main body 9201, a case 9202, a display 9203, a keyboard 9204, an external connection port 9205, a touchpad 9206, and the like. The display 9203 of this computer is one in which the same light-emitting elements as those described in the present embodiment mode are arranged in the form of a matrix. The light-emitting elements have the characteristics of high luminous efficiency and low drive voltage. In addition, short-circuiting due to impacts or the like caused by an external source can be prevented. Because the display 9203 made up of the light-emitting elements has the same characteristics, deterioration in the image quality of this computer is reduced and a shift to low power consumption can be achieved. Through such characteristics, because deterioration compensating functions and power supply circuits can be greatly reduced in number or size, a reduction in the size and weight of the main body 9201 and the case 9202 can be achieved. Because low power consumption, high picture quality, and a reduction in the size and weight of the computer produced using the light-emitting device of the present embodiment mode can be achieved, a device adapted for use in an applicable environment can be provided thereby. In addition, a computer that has a display which is able to withstand impacts by an external source can be provided.

The cellular phone of FIG. 7C is a cellular phone manufactured with a light-emitting device of the present embodiment mode and includes a main body 9401, a case 9402, a display 9403, an audio input 9404, an audio output 9405, operation keys 9406, an external connection port 9407, an antenna 9408, and the like. The display 9403 of this cellular phone is one in which the same light-emitting elements as those described in the present embodiment mode are arranged in the form of a matrix. The light-emitting elements have the characteristics of high luminous efficiency and low drive voltage. In addition, short-circuiting due to impacts or the like caused by an external source can be prevented. Because the display 9403 made up of the light-emitting elements has the same characteristics, deterioration in the image quality of this cellular phone is reduced and low power consumption can be achieved. Through such characteristics, because deterioration compensating functions and power supply circuits can be greatly reduced in number or size, a reduction in the size and weight of the main body 9401 and the case 9402 can be achieved. Because low power consumption, high picture quality, and a reduction in the size and weight of the cellular phone produced using the light-emitting device of the present embodiment mode can be achieved, a device adapted for portable use can be provided thereby. In addition, a cellular phone that has a display which is able to withstand impacts by an external source can be provided.

The camera of FIG. 7D is a camera manufactured with a light-emitting device of the present embodiment mode and includes a main body 9501, a display 9502, a case 9503, an external connection port 9504, a remote control receiver 9505, an image receiver 9506, a battery 9507, an audio input 9508, operation keys 9509, an eyepiece 9510, and the like. The display 9502 of this camera is one in which the same light-emitting elements as those described in the present embodiment mode are arranged in the form of a matrix. The light-emitting elements have the characteristics of high luminous efficiency and low drive voltage, and short-circuiting due to impacts or the like caused by an external source can be prevented. Because the display 9502 made up of the light-emitting elements has the same characteristics, deterioration in the image quality of this camera is reduced and low power consumption can be achieved. Through such characteristics, because deterioration compensating functions and power supply circuits can be greatly reduced in number or size, a reduction in the size and weight of the main body 9501 can be achieved. Because low power consumption, high picture quality, and a reduction in the size and weight of the camera produced using the light-emitting device of the present embodiment mode can be achieved, a device adapted for portable use can be provided thereby. In addition, a camera that has a display which is able to withstand impacts by an external source can be provided.

As described above, the scope and field of application of the light-emitting device of the present invention are extremely wide, and it is possible to apply the light-emitting device to electronic devices of any field. Use of the light-emitting device of the present invention allows an electronic device with a highly reliable display with low power consumption to be provided.

This application is based on Japanese Patent Application serial No. 2006-058737 filed with the Japan Patent Office on Mar. 3, 2006, the contents of which are hereby incorporated by reference.

What is claimed is:

1. A light-emitting element comprising:
a compound semiconductor substrate;
a first conductive layer over the compound semiconductor substrate;
a compound semiconductor layer over the compound semiconductor substrate, and
a second conductive layer over the compound semiconductor layer,
wherein both the compound semiconductor substrate and the compound semiconductor layer include a same element.

2. A light-emitting element comprising:
a compound semiconductor substrate;
a first conductive layer over the compound semiconductor substrate;
a compound semiconductor layer over the compound semiconductor substrate;
a dielectric layer over the compound semiconductor layer; and
a second conductive layer over the dielectric layer,
wherein both the compound semiconductor substrate and the compound semiconductor layer include a same element.

3. The light-emitting element according to claim 2, wherein the dielectric layer is a layer of any one selected from BaTiO₃, SrTiO₃, Ta₂O₅, Si₃N₄, SiO₂, Al₂O₃, and Y₂O₃.

4. The light-emitting element according to claim 1, wherein the compound semiconductor layer includes a host material, which is a compound containing an element belonging to group 2 or group 12 of the periodic table and an element belonging to group 16 of the periodic table, and an impurity element with a luminescent center.

5. The light-emitting element according to claim 2, wherein the compound semiconductor layer includes a host material, which is a compound containing an element belonging to group 2 or group 12 of the periodic table and an element belonging to group 16 of the periodic table, and an impurity element with a luminescent center.

6. The light-emitting element according to claim 4, wherein the host material includes any one selected from zinc sulfide (ZnS), calcium sulfide (CaS), and strontium sulfide (SrS), and the impurity element includes any one selected from manganese (Mn), europium (Eu), samarium (Sm), terbium (Tb), praseodymium (Pr), thulium (Tm), cerium (Ce), copper (Cu), silver (Ag), chlorine (Cl), and fluorine (F).

7. The light-emitting element according to claim 5, wherein the host material includes any one selected from zinc sulfide (ZnS), calcium sulfide (CaS), and strontium sulfide (SrS), and the impurity element includes any one selected from manganese (Mn), europium (Eu), samarium (Sm), terbium (Tb), praseodymium (Pr), thulium (Tm), cerium (Ce), copper (Cu), silver (Ag), chlorine (Cl), and fluorine (F).

8. The light-emitting element according to claim 1, wherein the second conductive layer has a light-transmitting property.

9. The light-emitting element according to claim 2, wherein the second conductive layer has a light-transmitting property.

10. A light-emitting element comprising:
a compound semiconductor substrate;
a first conductive layer over the compound semiconductor substrate;
a first compound semiconductor layer over the compound semiconductor substrate;
a second compound semiconductor layer over the first compound semiconductor layer; and
a second conductive layer over the second conductive layer,
wherein the compound semiconductor substrate and at least one of the first compound semiconductor layer and the second compound semiconductor layer include a same element.

11. A light-emitting element comprising:
a compound semiconductor substrate;
a first conductive layer over the compound semiconductor substrate;
a first compound semiconductor layer over the compound semiconductor substrate;
a second compound semiconductor layer over the first compound semiconductor layer;
a dielectric layer over the second compound semiconductor layer; and
a second conductive layer over the dielectric layer
wherein the compound semiconductor substrate and at least one of the first compound semiconductor layer and the second compound semiconductor layer include a same element.

12. The light-emitting element according to claim 11, wherein the dielectric layer is a layer of any one selected from BaTiO₃, SrTiO₃, Ta₂O₅, Si₃N₄, SiO₂, Al₂O₃, and Y₂O₃.

13. The light-emitting element according to claim 10, wherein the compound semiconductor layer includes a host material, which is a compound containing an element belonging to group 2 or group 12 of the periodic table and an element belonging to group 16 of the periodic table, and an impurity element with a luminescent center; and the second compound semiconductor layer contains a chalcopyrite compound.

14. The light-emitting element according to claim 11, wherein the compound semiconductor layer includes a host material, which is a compound containing an element belonging to group 2 or group 12 of the periodic table and an element belonging to group 16 of the periodic table, and an impurity element with a luminescent center; and the second compound semiconductor layer contains a chalcopyrite compound.

15. The light-emitting element according to claim 13, wherein the host material includes any one selected from zinc sulfide (ZnS), calcium sulfide (CaS), or strontium sulfide (SrS); and the impurity element includes one of any of manganese (Mn), europium (Eu), samarium (Sm), terbium (Tb), praseodymium (Pr), thulium (Tm), cerium (Ce), copper (Cu), silver (Ag), chlorine (Cl), or fluorine (F).

16. The light-emitting element according to claim 14, wherein the host material includes any one selected from zinc sulfide (ZnS), calcium sulfide (CaS), or strontium sulfide (SrS); and the impurity element includes one of any of manganese (Mn), europium (Eu), samarium (Sm), terbium (Tb), praseodymium (Pr), thulium (Tm), cerium (Ce), copper (Cu), silver (Ag), chlorine (Cl), or fluorine (F).

17. The light-emitting element according to claim 1, further comprising:
a layer including an uneven surface interposed between the compound semiconductor substrate and the compound semiconductor layer.

18. The light-emitting element according to claim 2, further comprising:
a layer including an uneven surface interposed between the compound semiconductor substrate and the compound semiconductor layer.

19. The light-emitting element according to claim 10, further comprising:
a layer including an uneven surface interposed between the compound semiconductor substrate and the first compound semiconductor layer.

20. The light-emitting element according to claim 11, further comprising:
a layer including an uneven surface interposed between the compound semiconductor substrate and the first compound semiconductor layer.

21. The light-emitting element according to claim 1, wherein the compound semiconductor substrate has an uneven surface.

22. The light-emitting element according to claim 2, wherein the compound semiconductor substrate has an uneven surface.

23. The light-emitting element according to claim 10, wherein the compound semiconductor substrate has an uneven surface.

24. The light-emitting element according to claim 11, wherein the compound semiconductor substrate has an uneven surface.

25. The light-emitting element according to claim 1, wherein the compound semiconductor substrate is a p-type semiconductor.

26. The light-emitting element according to claim 2, wherein the compound semiconductor substrate is a p-type semiconductor.

27. The light-emitting element according to claim 10, wherein the compound semiconductor substrate is a p-type semiconductor.

28. The light-emitting element according to claim 11, wherein the compound semiconductor substrate is a p-type semiconductor.

29. The light-emitting element according to claim 1, wherein the compound semiconductor substrate is a substrate of GaAs, GaP, or InP.

30. The light-emitting element according to claim 2, wherein the compound semiconductor substrate is a substrate of GaAs, GaP, or InP.

31. The light-emitting element according to claim 10, wherein the compound semiconductor substrate is a substrate of GaAs, GaP, or InP.

32. The light-emitting element according to claim 11, wherein the compound semiconductor substrate is a substrate of GaAs, GaP, or InP.

33. A method for manufacturing a light-emitting element comprising the steps of:
forming a compound semiconductor layer over a compound semiconductor substrate;
diffusing an element included in the compound semiconductor substrate into the compound semiconductor layer by heat treatment;
forming a first conductive layer over the compound semiconductor substrate; and
forming a second conductive layer over the compound semiconductor layer.

34. A method for manufacturing a light-emitting element comprising the steps of:
forming an uneven surface over a compound semiconductor substrate by chemical treatment;
forming a compound semiconductor layer over the uneven surface of the compound semiconductor substrate;
diffusing an element included in the compound semiconductor substrate into the compound semiconductor layer by heat treatment;
forming a first conductive layer over the compound semiconductor substrate; and
forming a second conductive layer over the compound semiconductor layer.

35. The method for manufacturing a light-emitting element according to claim 33, wherein a dielectric layer is formed between the compound semiconductor layer and the second conductive layer.

36. The method for manufacturing a light-emitting element according to claim 34, wherein a dielectric layer is formed between the compound semiconductor layer and the second conductive layer.

37. The method for manufacturing a light-emitting element according to claim 33, wherein a layer containing a host material, which is a compound containing an element belonging to group 2 or group 12 of the periodic table and an element belonging to group 16 of the periodic table, and an impurity element with a luminescent center is used as the compound semiconductor layer.

38. The method for manufacturing a light-emitting element according to claim 34, wherein a layer containing a host material, which is a compound containing an element belonging to group 2 or group 12 of the periodic table and an element belonging to group 16 of the periodic table, and an impurity element with a luminescent center is used as the compound semiconductor layer.

39. The method for manufacturing a light-emitting element according to claim 37, wherein any one selected from zinc sulfide (ZnS), calcium sulfide (CaS), and strontium sulfide (SrS) is used as the host material; and any one selected from manganese (Mn), europium (Eu), samarium (Sm), terbium (Tb), praseodymium (Pr), thulium (Tm), cerium (Ce), copper (Cu), silver (Ag), chlorine (Cl), and fluorine (F) is used as the impurity element.

40. The method for manufacturing a light-emitting element according to claim 38, wherein any one selected from zinc sulfide (ZnS), calcium sulfide (CaS) and strontium sulfide (SrS) is used as the host material; and any one selected from manganese (Mn), europium (Eu), samarium (Sm), terbium (Tb), praseodymium (Pr), thulium (Tm), cerium (Ce), copper (Cu), silver (Ag), chlorine (Cl), and fluorine (F) is used as the impurity element.

41. The method for manufacturing a light-emitting element according to claim 33, wherein any one selected from carbon (C), silicon (Si), germanium (Ge), aluminum (Al), gallium (Ga), indium (In), nitrogen (N), phosphorous (P), arsenic (As) and antimony (Sb) is introduced into the compound semiconductor layer.

42. The method for manufacturing a light-emitting element according to claim 34, wherein any one selected from carbon (C), silicon (Si), germanium (Ge), aluminum (Al), gallium (Ga), indium (In), nitrogen (N), phosphorous (P), arsenic (As) and antimony (Sb) is introduced into the compound semiconductor layer.

43. A method for manufacturing a light-emitting element comprising the steps of:
forming a first compound semiconductor layer over a compound semiconductor substrate;
forming a second compound semiconductor layer over the first compound semiconductor layer;
diffusing an element included in the compound semiconductor substrate into the first compound semiconductor layer or into the second compound semiconductor layer by heat treatment;
forming a first conductive layer over the compound semiconductor substrate; and
forming a second conductive layer over the second compound semiconductor substrate.

44. A method for manufacturing a light-emitting element comprising the steps of:
forming an uneven surface over a compound semiconductor substrate by chemical treatment;
forming a first compound semiconductor layer over the uneven surface of the compound semiconductor substrate;
forming a second compound semiconductor layer over the first compound semiconductor layer;
diffusing an element included in the compound semiconductor substrate into the first compound semiconductor layer or into the second compound semiconductor layer by heat treatment;
forming a first conductive layer over the compound semiconductor substrate; and
forming a second conductive layer over the second compound semiconductor layer.

45. The method for manufacturing a light-emitting element according to claim 43, wherein a dielectric layer is formed between the second compound semiconductor layer and the second conductive layer.

46. The method for manufacturing a light-emitting element according to claim 44, wherein a dielectric layer is formed between the second compound semiconductor layer and the second conductive layer.

47. The method for manufacturing a light-emitting element according to claim 43, wherein a layer containing a host material, which is a compound containing an element belonging to group 2 or group 12 of the periodic table and an element belonging to group 16 of the periodic table, and an impurity element with a luminescent center is used as the first compound semiconductor layer; and a chalcopyrite compound is used as the second compound semiconductor layer.

48. The method for manufacturing a light-emitting element according to claim 44, wherein a layer containing a host material, which is a compound containing an element belonging to group 2 or group 12 of the periodic table and an element belonging to group 16 of the periodic table, and an impurity element with a luminescent center is used as the first compound semiconductor layer; and a chalcopyrite compound is used as the second compound semiconductor layer.

49. The method for manufacturing a light-emitting element according to claim 47, wherein any one selected from zinc sulfide (ZnS), calcium sulfide (CaS), and strontium sulfide (SrS) is used as the host material; and any one selected from manganese (Mn), europium (Eu), samarium (Sm), terbium (Tb), praseodymium (Pr), thulium (Tm), cerium (Ce), copper (Cu), silver (Ag), chlorine (Cl), and fluorine (F) is used as the impurity element.

50. The method for manufacturing a light-emitting element according to claim 48, wherein any one selected from zinc sulfide (ZnS), calcium sulfide (CaS), and strontium sulfide (SrS) is used as the host material; and any one selected from manganese (Mn), europium (Eu), samarium (Sm), terbium (Tb), praseodymium (Pr), thulium (Tm), cerium (Ce), copper (Cu), silver (Ag), chlorine (Cl), and fluorine (F) is used as the impurity element.

51. The method for manufacturing a light-emitting element according to claim 43, wherein any one selected from carbon (C), silicon (Si), germanium (Ge), aluminum (Al), gallium (Ga), indium (In), nitrogen (N), phosphorous (P), arsenic (As) and antimony (Sb) is introduced into the first compound semiconductor layer.

52. The method for manufacturing a light-emitting element according to claim 44, wherein any one selected from carbon (C), silicon (Si), germanium (Ge), aluminum (Al), gallium (Ga), indium (In), nitrogen (N), phosphorous (P), arsenic (As) and antimony (Sb) is introduced into the first compound semiconductor layer.

53. The method for manufacturing a light-emitting element according to claim 43, wherein chemical treatment is performed with a mixture of sulfuric acid and hydrogen peroxide solution, a mixture of orthophosphoric acid and hydrogen peroxide solution, aqueous sodium hydroxide, aqueous citric acid, a mixture of bromine and ethanol, a mixture of hydrochloric acid and orthophosphoric acid, or a mixture of hydrochloric acid and nitric acid.

54. The method for manufacturing a light-emitting element according to claim 44, wherein chemical treatment is performed with a mixture of sulfuric acid and hydrogen peroxide solution, a mixture of orthophosphoric acid and hydrogen peroxide solution, aqueous sodium hydroxide, aqueous citric acid, a mixture of bromine and ethanol, a mixture of hydrochloric acid and orthophosphoric acid, or a mixture of hydrochloric acid and nitric acid.

55. The method for manufacturing a light-emitting element according to claim 43, wherein a GaAs, a GaP, or an InP substrate is used for the compound semiconductor substrate.

56. The method for manufacturing a light-emitting element according to claim 44, wherein a GaAs, a GaP, or an InP substrate is used for the compound semiconductor substrate.

57. The method for manufacturing a light-emitting element according to claim 43, wherein a p-type compound semiconductor substrate is used for the compound semiconductor substrate.

58. The method for manufacturing a light-emitting element according to claim 44, wherein a p-type compound semiconductor substrate is used for the compound semiconductor substrate.

59. The method for manufacturing a light-emitting element according to claim 43, wherein laser irradiation is used for the heat treatment.

60. The method for manufacturing a light-emitting element according to claim 44, wherein laser irradiation is used for the heat treatment.

61. The method for manufacturing a light-emitting element according to claim 43, further comprising the steps of:
a treated layer including an uneven surface interposed between the compound semiconductor substrate and the compound semiconductor layer.

62. The method for manufacturing a light-emitting element according to claim 44, further comprising the steps of:
a treated layer including an uneven surface interposed between the compound semiconductor substrate and the first compound semiconductor layer.
